(19) United States
(12) Patent Application Publication
(10) Pub. No.: US 2008/0197429 A1
(43) Pub. Date: Aug. 21, 2008

(54) SEMICONDUCTOR DEVICE AND METHOD OF MANUFACTURING SAME

(76) Inventors: Motoyuki Sato, Kanagawa-ken (JP); Tomohiro Saito, Kanagawa-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/033,566

(22) Filed: Feb. 19, 2008

(30) Foreign Application Priority Data
Feb. 19, 2007 (JP) 2007-037393

(51) Int. Cl. H01L 29/78; H01L 21/4763

(52) U.S. Cl. 257/412; 438/591; 257/E21.495; 257/E29.255

(57) ABSTRACT

A semiconductor device includes: a silicon oxide film; a metal silicate insulating film provided on the silicon oxide film and having a higher dielectric constant than the silicon oxide film; and a gate electrode provided on the metal silicate insulating film. A composition ratio of a metal element in the metal silicate insulating film on a side closer to the gate electrode is lower than a composition ratio of the metal element in the metal silicate insulating film on a side closer to the silicon oxide film.

### CROSS-REFERENCE TO RELATED APPLICATIONS

This application is based upon and claims the benefit of priority from the prior Japanese Patent Application No. 2007-037393, filed on Feb. 19, 2007; the entire contents of which are incorporated herein by reference.

### BACKGROUND OF THE INVENTION

1. Field of the Invention

This invention relates to a semiconductor device and a method of manufacturing the same, and more particularly to a semiconductor device using a metal silicate insulating film as a gate insulating film and a method of manufacturing the same.

2. Background Art

Downscaling large-scale integrated circuits requires thinning of the gate insulating film. In a silicon oxide film or a silicon oxynitride film used conventionally, increasing a leak current caused from film thinning limits the film thinning. Hence, it is proposed that degradation in current driving capability in a transistor is suppressed while suppressing the leak current by using a metal silicate film or its nitride film with a dielectric constant higher than that of the silicon oxide film or silicon oxynitride film for the gate insulating film to increase a physical film thickness. Among metal silicate films, a hafnium silicate film is superior to other materials in high thermal stability and high carrier mobility, and is under development. For example, Japanese Patent Application Disclosure JP-A 2005-217272 (Kokai) discloses the gate insulating film based on a HfSiON film.

However, when the HfSiON film is used as the gate insulating film and polycrystalline silicon is used as the gate electrode, hafnium reacts with silicon, thereby resulting in silicidization of the gate electrode. Such silicidization may cause variation of a threshold value voltage.

Furthermore, with downscaling, adoption of a nickel silicide gate electrode producing no gate depletion layer instead of polycrystalline silicon is also proposed. However, when the nickel silicide gate electrode containing boron as an impurity is combined with the hafnium silicate insulating film, nickel contained in the gate electrode penetrates the gate insulating film and diffuses into the silicon substrate, thereby causing the increase of the gate leak current.

### SUMMARY OF THE INVENTION

According to an aspect of the invention, there is provided a semiconductor device including: a silicon oxide film; a metal silicate insulating film provided on the silicon oxide film and having a higher dielectric constant than the silicon oxide film; and a gate electrode provided on the metal silicate insulating film, a composition ratio of a metal element in the metal silicate insulating film on a side closer to the gate electrode being lower than a composition ratio of the metal element in the metal silicate insulating film on a side closer to the silicon oxide film.

According to another aspect of the invention, there is provided a semiconductor device including: a metal silicate insulating film; a silicon nitride film provided on the metal silicate insulating film; and a nickel silicide gate electrode provided on the silicon nitride film, at least a part of the nickel silicide gate electrode containing boron.

According to a still another aspect of the invention, there is provided a method of manufacturing a semiconductor device, including: depositing a metal silicate insulating film on a silicon oxide film by supplying a metal source gas, a silicon source gas and an oxygen source gas to a surface of the silicon oxide film, the metal silicate insulating film having a higher dielectric constant than the silicon oxide film, and forming a gate electrode on the metal silicate insulating film, the depositing including reducing the supplying amount of the metal source gas during deposition of the metal silicate insulating film.

### BRIEF DESCRIPTION OF THE DRAWINGS

FIG. 1 is a schematic view illustrating the relevant part of the cross-sectional structure of a semiconductor device according to a first embodiment of the invention;

FIG. 2 is a view showing a TEM (Transmission Electron Microscope) image from the MIS structure portion of the semiconductor device according to the first embodiment of the same;

FIG. 3 is a figure showing an atomic profile in the gate insulating film of the semiconductor device according to the first embodiment of the same, measured by RBS (Rutherford Backscattering Spectroscopy) method;

FIG. 4 is a graphical diagram showing electron mobility for providing a HfSiON film (Low-Hf layer) having a low composition ratio of Hf on the side in contact with the gate electrode as a gate insulating film, for not providing the HfSiON film having the low composition of Hf, and for providing a silicon oxide film only, respectively;

FIG. 5 is an IV characteristic diagram of a p-type MIS structure;

FIG. 6 is a PBTI (positive bias temperature instabilities) characteristic diagram showing time (life) required for variation of threshold value voltage Vₜₕ up to 50 (mV) under application of stress voltage Vg (V), for an n-type MIS structure;

FIG. 7 is a NBTI (negative bias temperature instabilities) characteristic diagram showing time (life) required for variation of the threshold value voltage Vₜₕ up to 50 (mV) under application of the stress voltage Vg (V), for a p-type MIS structure;

FIG. 8 is a TDDB (time dependent dielectric breakdown) characteristic diagram showing a breakdown life with time of the gate insulating film under application of the stress voltage Vg (V);

FIG. 9 is a schematic view illustrating the relevant part of the cross-sectional structure of a semiconductor device according to a second embodiment of the invention;

FIG. 10 is a schematic cross section enlarging the MIS structure portion of the semiconductor device according to the second embodiment of the same;

FIG. 11 is a process cross section showing a method of manufacturing a semiconductor device according to the second embodiment of the same;

FIG. 12 is a process cross section following after FIG. 11;

FIG. 13 is a process cross section following after FIG. 12;

FIG. 14 is a schematic cross section enlarging the MIS structure portion of a semiconductor device according to a fourth embodiment of the invention;

FIG. 15 is a graphic diagram showing results of measuring leak currents for each structure, the structure provided with the HfSiON film (Low-Hf layer) having the low composition ratio of Hf on the side of the gate insulating film in contact with the gate electrode, the structure provided with the silicon nitride film on the side of the gate insulating film in contact with the gate electrode, and the structure not provided with HfSiON film 27 having the low composition ratio of Hf in the gate insulating film; and

FIG. 16 is a TEM image showing a state that nickel in the gate electrode penetrates the gate insulating film and diffuses into the silicon substrate.

### DETAILED DESCRIPTION OF THE INVENTION

Embodiments of the invention will now be described with reference to the drawings.

### First Embodiment

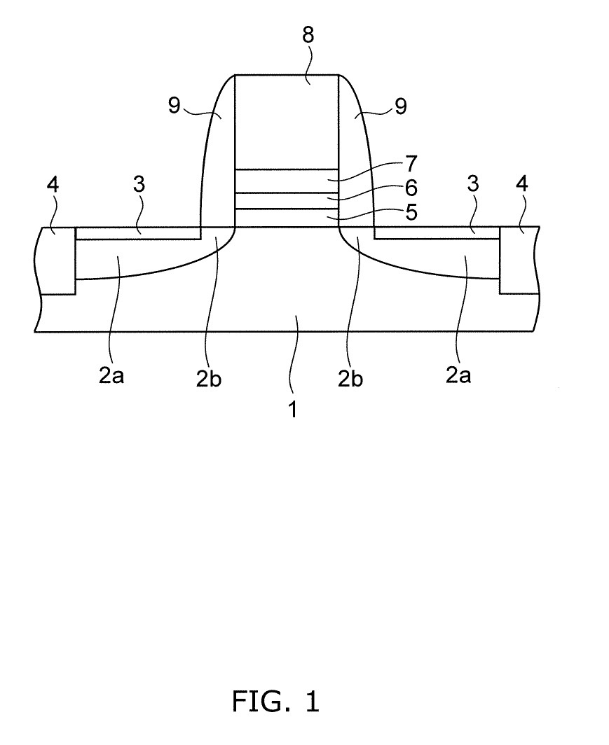

FIG. 1 is a schematic view illustrating the relevant part of the cross-sectional structure of a semiconductor device according to a first embodiment of the invention. FIG. 1 shows the cross-sectional structure of an element insulated from other element by an element isolation region 4 illustratively made of oxidized silicon.

The semiconductor device according to the embodiment has the MIS (Metal Insulator Semiconductor) structure provided with a gate electrode 8 via gate insulating films 5 through 7 on a silicon layer (silicon substrate) 1.

In the superficial portion of the silicon layer 1, a deep impurity diffusion region 2a and a shallow impurity diffusion region 2b with an opposite conductivity type to the superficial portion are formed selectively. These impurity diffusion regions 2a and 2b are formed in a self-aligning way by an ion implantation process using the MIS structure portion as a mask and a following thermal diffusion process. The impurity diffusion region 2a functions as a source/drain region, and its surface has a metal silicon compound region 3 formed thereon for decreasing the resistance.

The superficial portion of the silicon layer 1 between impurity diffusion regions 2b functions as a channel formation region and the gate electrode 8 is provided via the gate insulating films 5 through 7 on this channel formation region. A side wall insulating film 9 illustratively made of oxidized silicon is provided on side walls of the gate electrode 8 and the gate insulating films 5 through 7.

In this embodiment, a silicon oxide film and a metal silicate insulating film (including nitride) as a so-called high-k film having a higher dielectric constant than the silicon oxide film are used for the gate insulating film. The metal silicate insulating film is, for example, a hafnium silicate insulating film, for further details a HfSiON film containing nitrogen.

A silicon oxide film 5 illustratively formed by a thermal oxidation method is formed on the surface of the channel formation region. The HfSiON film 6 having a Hf/(Hf+Si) ratio of illustratively 50% or more is formed on the silicon oxide film 5, and the HfSiON film 7 having a Hf/(Hf+Si) ratio less than that of the HfSiON film 6 is formed on the HfSiON film 6. The gate electrode 8 illustratively made of polycrystalline silicon is formed on the HfSiON film 7.

The HfSiON films 6, 7 are obtained by nitridation treatment of the HfSiON film after formation of the HfSiON film by a MOCVD (Metal Organic Chemical Vapor Deposition) method, for example.

For example, a silicon wafer (the silicon oxide film 5 is formed on its surface) heated to 650° C. is placed on a susceptor, the HfSiON film having a high Hf composition ratio is formed at first by supplying, for example, tetradiethylaminohafnium as hafnium source gas, for example, diethylsilane as silicon source gas, and oxygen onto the surface, and then the HfSiON film having a lower Hf composition ratio than the HfSiON film having the high Hf composition ratio is formed continuously on the HfSiON film having the high Hf composition ratio by reducing the amount supplied of the hafnium source gas during the formation of HfSiON films.

In this process, the HfSiON film having the low Hf composition ratio can be formed on the HfSiON film having the high Hf composition ratio by only varying the amount of supply of the hafnium source gas, and the HfSiON film having the high Hf composition ratio formed in advance is not damaged. It is noted that the HfSiON film is not limited to the MOCVD method to be formed, but may be formed by an ALD (Atomic Layer Deposition) method and a sputtering method or the like.

The formation of the HfSiON films is followed by the nitridation treatment. Nitrogen is introduced into the HfSiON films by a plasma nitridation method or an ammonia nitridation method supplying ammonia gas onto the surface of the heated wafer, for example, hereafter anneal treatment is performed in nitrogen gas containing oxygen gas in a ratio of 0.1 percent, for example. Then the HfSiON films 6, 7 are obtained.

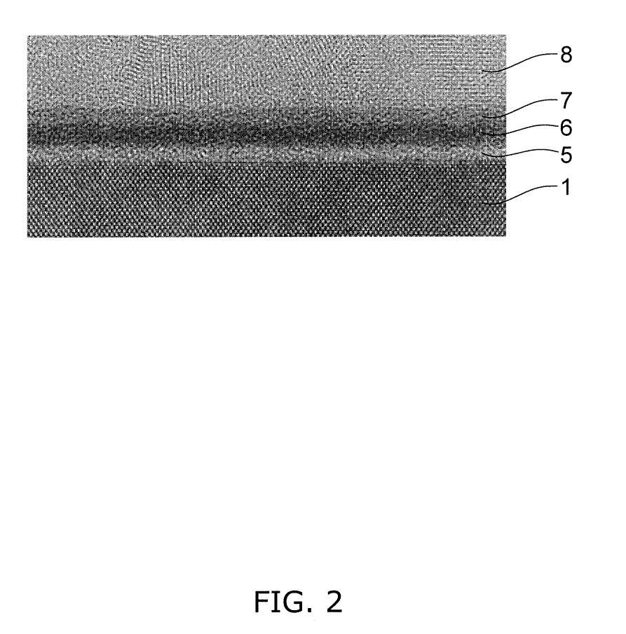

FIG. 2 shows a TEM (Transmission Electron Microscope) image from the MIS structure portion of the semiconductor device according to this embodiment.

Hafnium atom diffusion from the HfSiON film 6 having the high Hf composition ratio to the silicon oxide film 5 and the HfSiON film 7 having the low Hf composition ratio is not observed and a three layers structure having relatively clear boundaries between the silicon oxide film 5, the HfSiON film 6 and the HfSiON film 7 can be confirmed.

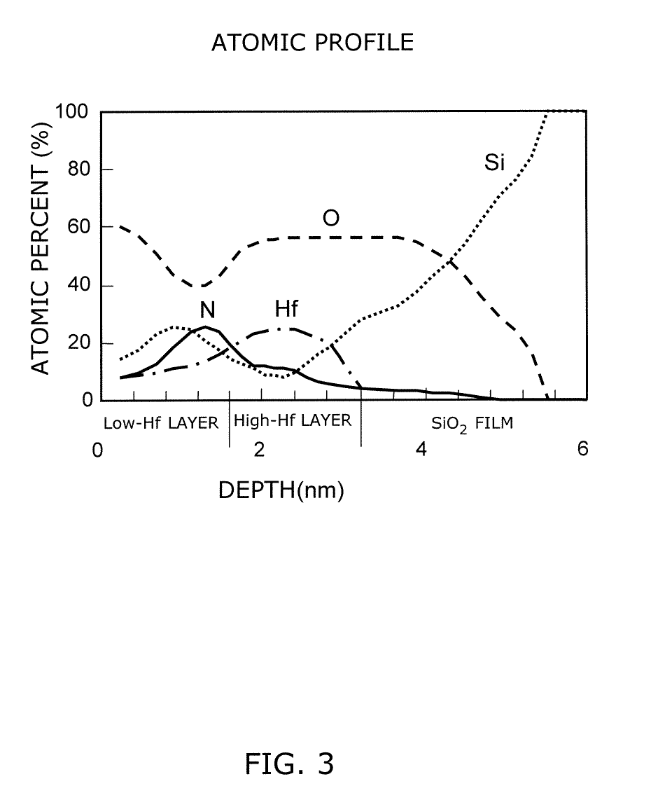

FIG. 3 shows an atomic profile in the gate insulating films 5 through 7 measured by a RBS (Rutherford Backscattering Spectroscopy) method.

The horizontal axis represents a depth (nm) along the substrate direction in assuming the boundary level between the gate electrode 8 and the HfSiON film 7 having the low Hf composition ratio as a reference (zero), and the vertical axis represents an atomic percent of each atom, Si, O, Hf and N. Moreover, in FIG. 3, “Low-Hf layer” represents the HfSiON film 7 having the low Hf composition ratio, “High-Hf layer” represents the HfSiON film 6 having the high Hf composition ratio, and SiO₂ film represents the silicon oxide film 5.

In this embodiment, the HfSiON films 6, 7 having a higher dielectric constant than the silicon oxide film 5 are provided on the silicon oxide film 5, thus degradation of current driving capability can be suppressed by realizing a film thickness electrically equivalent to a thin oxide film while an insulating film thickness (physical film thickness) being thick in order to suppress a leak current. From this viewpoint, it is preferable that the Hf/(Hf+Si) ratio in the HfSiON film 6 having the high Hf composition ratio on the side in contact with the silicon oxide film 5 is greater than or equal to 50 percent.

Furthermore, in this embodiment, a reaction between hafnium and polycrystalline silicon (polysilicon) as a gate electrode material can be suppressed by reducing the Hf composition ratio in the HfSiON film 7 on the side in contact with the gate electrode 8 less than the Hf composition ratio in the HfSiON film 6 on the side in contact with the silicon oxide film 5. Consequently variation (increase) of threshold value voltage due to silicidization of the gate electrode 8 can be suppressed.

The inventors found, as a consequence of diligent discussion, that an effect enough to suppress the variation of the threshold value voltage is obtained for the Hf/(Hf+Si) ratio in the HfSiON film 7 being less than or equal to 6 percent. Moreover, it is also found that decreasing the Hf/(Hf+Si) ratio less than or equal to 1 percent causes increase of the leak current. Therefore, it is preferable that the Hf/(Hf+Si) ratio in the HfSiON film 7 on the side in contact with the gate electrode 8 is from 1 percent to 6 percent inclusive.

As described previously, while the HfSiON films 6, 7 are formed by the nitridation of the HfSiON film after the formation of the HfSiON film of two layers having different Hf composition ratios in advance, nitrogen is likely to form a bond to silicon, thus the structure is obtained, which much nitrogen piles up in the HfSiON film 7 containing more content of silicon and being in contact with the gate electrode 8 of polysilicon. That is, nitrogen can be located away from the channel formation region, and carrier mobility in the channel can be improved.

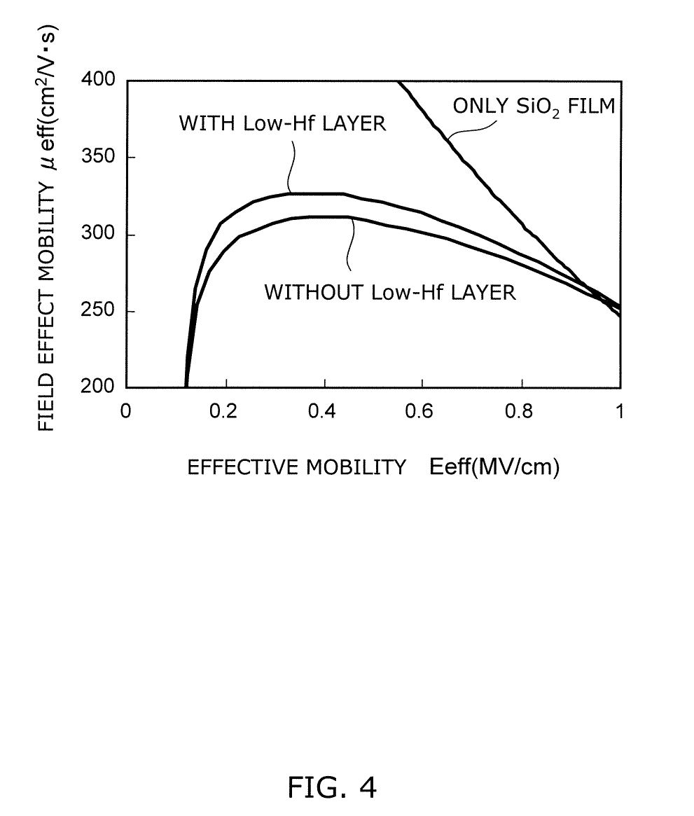

FIG. 4 is a graphical diagram showing electron mobility for providing the HfSiON film (Low-Hf layer) 7 having the low composition ratio of Hf on the side in contact with the gate electrode as the gate insulating film (this embodiment), for not providing the HfSiON film 7 having the low composition ratio of Hf, and for providing the silicon oxide film (SiO₂ film) 5 only, respectively. The horizontal axis represents effective mobility E_{eff} (MV/cm), and the vertical axis represents field effect mobility μ_{eff} (cm²/V·s).

As shown in FIG. 4, the electron carrier mobility is more improved for providing the HfSiON film 7 having the low Hf composition ratio on the side in contact with the gate electrode than for not providing it. This is because of an effect obtained by locating nitrogen responsible for the decrease of the mobility away from the substrate (channel formation region). Moreover, reducing hafnium concentration in the surface of the gate insulating film produces an effect of suppressing pinning of the Fermi energy, too.

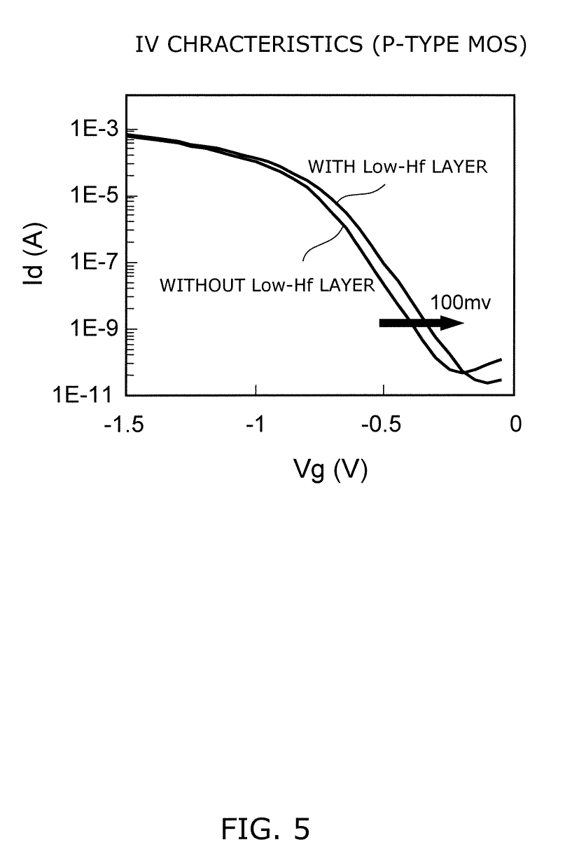

FIG. 5 is an IV characteristic diagram of a p-type MIS structure. The horizontal axis represents gate voltage Vg (V) and the vertical axis represents a drain current Id (A).

It is shown that providing the HfSiON film (Low-Hf layer) 7 having the low Hf composition ratio on the side in contact with the gate electrode suppresses a reaction of hafnium between polycrystalline silicon of the gate electrode, causes a shift of the threshold value voltage of the p-type MIS structure to a positive direction, and the pinning of the Fermi energy is suppressed.

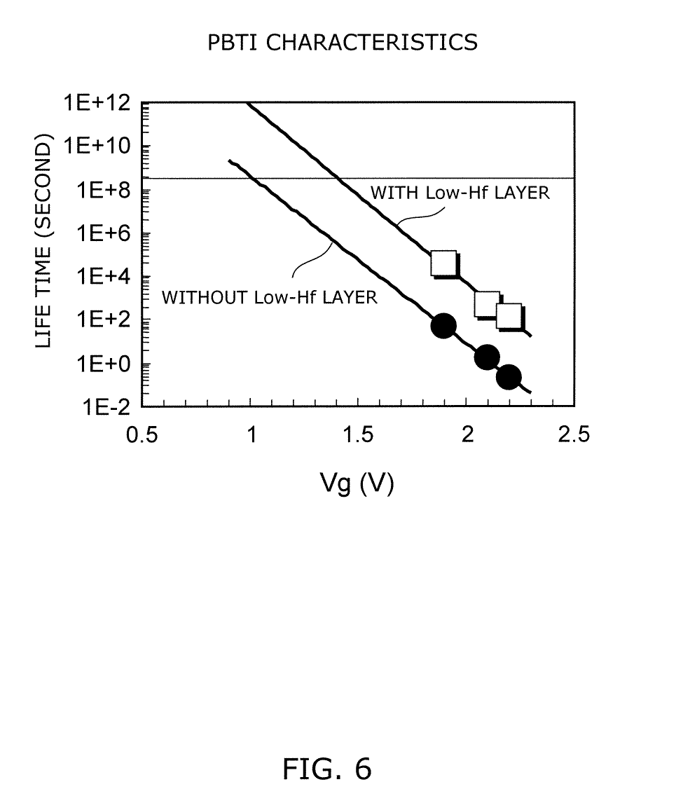

FIG. 6 is a PBTI (positive bias temperature instabilities) characteristic diagram showing time (life) required for variation of the threshold value voltage Vₜₕ up to 50 (mV) under application of the stress voltage Vg (V), for an n-type MIS structure.

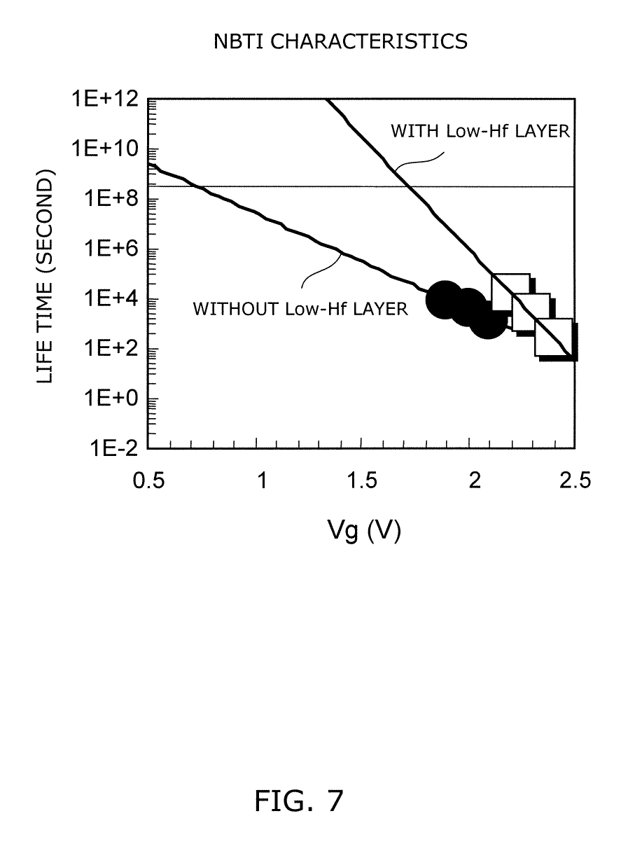

FIG. 7 is a NBTI (negative bias temperature instabilities) characteristic diagram showing time (life) required for variation of the threshold value voltage Vₜₕ up to 50 (mV) under application of the stress voltage Vg (V), for the p-type MIS structure.

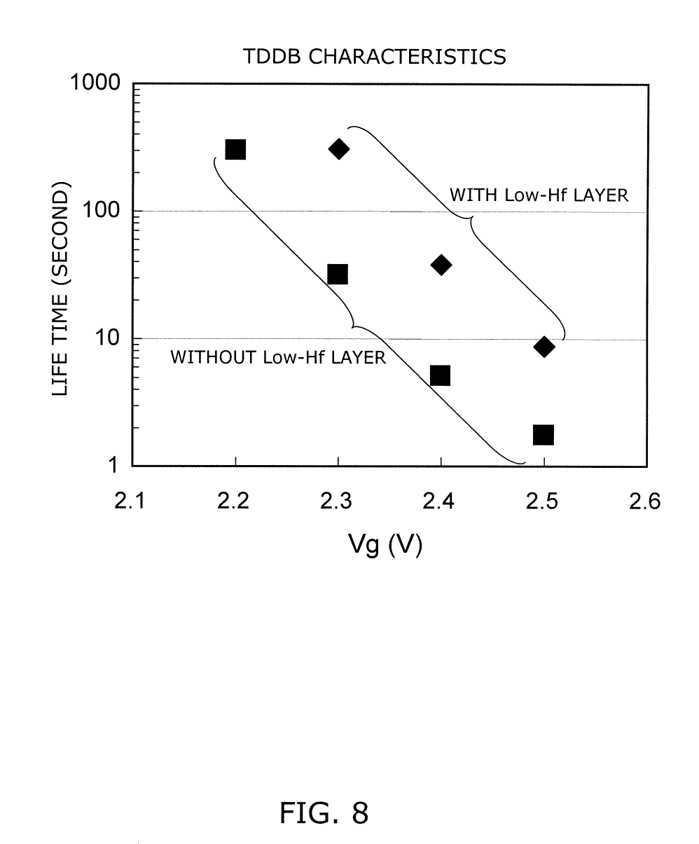

FIG. 8 is a TDDB (time dependent dielectric breakdown) characteristic diagram showing a breakdown life with time of the gate insulating film under application of the stress voltage Vg (Vₜₕ).

These FIGS. 6 through 8 show that providing the HfSiON film (Low-Hf layer) 7 having the low Hf composition ratio on the side in contact with the gate electrode can improve the life time and produces superior long-term reliability in comparison with not providing.

It is noted that the gate electrode 8 may be based on, for example, tungsten (W), ruthenium (Ru), tantalum carbide (TaC), titanium nitride (TiC), tantalum nitride (TiN), rhenium (Re) or the like other than polycrystalline silicon.

### Second Embodiment

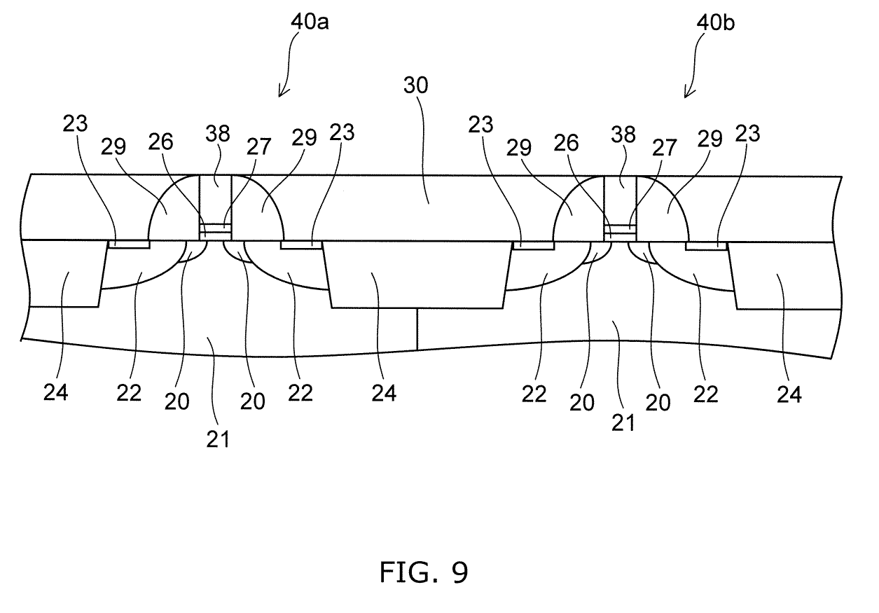

FIG. 9 is a schematic view illustrating the relevant part of the cross-sectional structure of a semiconductor device according to a second embodiment of the invention. FIG. 9 shows the cross-sectional structure of an adjacent n-type MIS structure 40a and a p-type MIS structure 40b being insulated and isolated by an element isolation region 24 illustratively made of oxidized silicon.

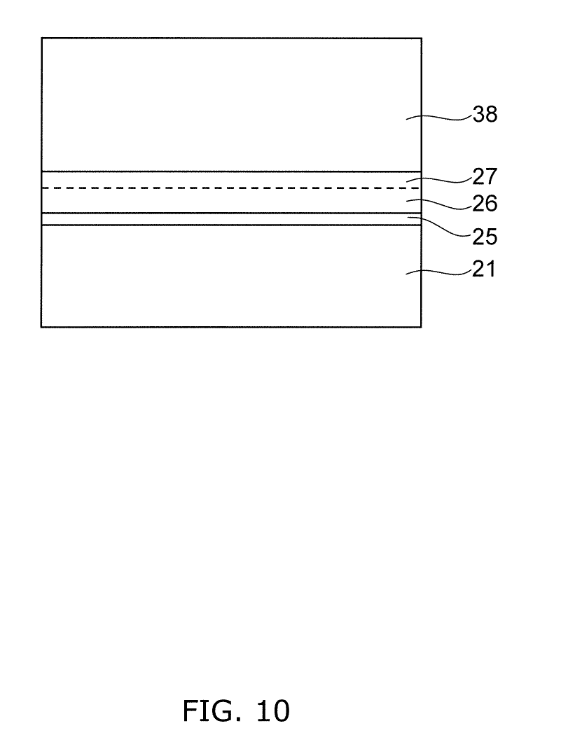

FIG. 10 is a schematic cross section enlarging the MIS structure portion of the semiconductor device of the same.

The semiconductor device according to the embodiment has the MIS structure provided with a gate electrode 38 via gate insulating films 26, 27 on a silicon layer (silicon substrate) 21.

In the superficial portion of the silicon layer 21, a deep impurity diffusion region 22 and a shallow impurity diffusion region 20 with an opposite conductivity type to the superficial portion are formed selectively. These impurity diffusion regions 22 and 20 are formed in a self-aligning way by an ion implantation process using the MIS structure portion as a mask and a following thermal diffusion process. The impurity diffusion region 22 functions as a source/drain region, and its surface has a metal silicon compound region 23 formed thereon for decreasing the resistance.

In the n-type MIS structure 40a, the conductivity type of the superficial portion of the silicon layer 21 is p-type, and the n-type impurity diffusion region (source/drain region) 22 is formed on its surface. In the p-type MIS structure 40b, the conductivity type of the superficial portion of the silicon layer 21 is n-type, and the p-type impurity diffusion region (source/drain region) 22 is formed on its surface.

The superficial portion of the silicon layer 21 between the impurity diffusion regions 20 functions as the channel formation region and the gate electrode 38 is provided via the gate insulating films 26, 27 on this channel formation region. A side wall insulating film 29 illustratively made of oxidized silicon is provided on the side wall of the gate electrode 38 and the gate insulating films 26, 27, and an interlayer insulating film 30 is provided so as to cover the side wall insulating film 29.

In this embodiment, a metal silicate insulating film (including nitride) as a so-called high-k film having a higher dielectric constant than the silicon oxide film is used for the gate insulating film. The metal silicate insulating film is, for example, a hafnium silicate insulating film, for further details a HfSiON film containing nitrogen.

A silicon oxide film 25 illustratively formed by the thermal oxidation method is formed on the surface of the channel formation region as shown in FIG. 10. The HfSiON films 26, 27 are formed on the silicon oxide film 25. In the HfSiON films 26, 27, the Hf/(Hf+Si) ratio of the HfSiON film 27 on the side in contact with the gate electrode 38 is lower than the Hf/(Hf+Si) ratio of the HfSiON film 26 on the side in contact with the silicon oxide film 25. The Hf/(Hf+Si) ratio of the HfSiON film 27 on the side in contact with the gate electrode 38 is, for example, greater than 0 percent and less than or equal to 30 percent.

The gate electrode 38 is formed on the HfSiON film 27. The gate electrode 38 is a nickel silicide gate electrode obtained by a silicidization reaction of nickel diffused from an upper portion, after deposition and fabrication of polycrystalline silicon.

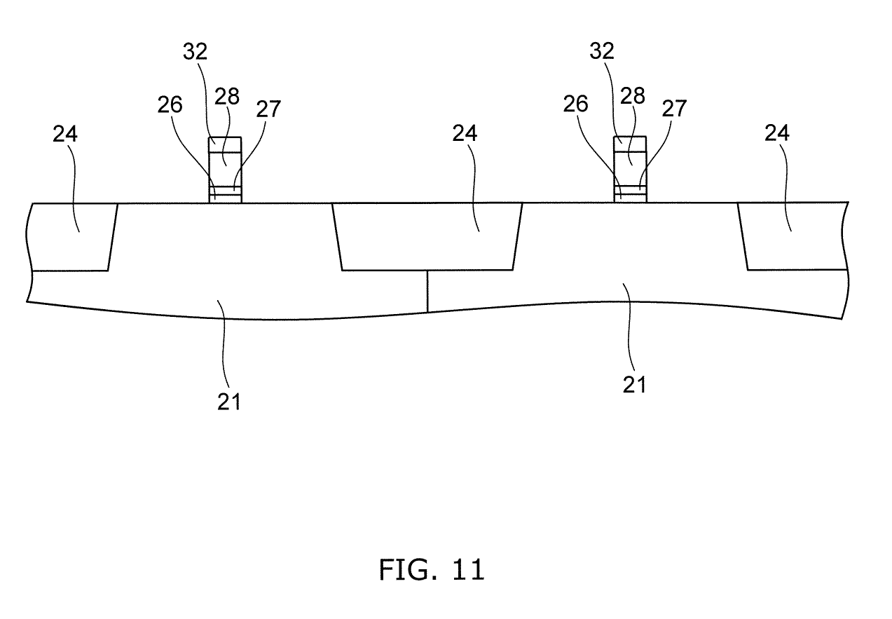

FIGS. 11 through 13 are process cross sections showing a method of manufacturing a semiconductor device according to the embodiment.

First an element isolation region 24 is formed in a superficial portion of a silicon layer (silicon substrate) 21. This is formed as follows.

A silicon nitride film serving as a mask is formed via a buffer film on a surface of the silicon layer 21. Next the silicon nitride film, the buffer film and the silicon layer 21 are etched selectively to a specified depth using a patterned resist. After the resist is removed and a silicon oxide film is deposited over the entire surface, its surface is planarized by a CMP (Chemical Mechanical Polishing) method, for example. Hereafter the element isolation region 24 with a STI (Shallow Trench Isolation) structure is obtained by removing the silicon nitride mask.

Next, after pretreatment using dilute hydrofluoric acid, an interface layer of a silicon oxide film is formed by slightly oxidizing the substrate surface. Then a hafnium silicate (HfSiON) film with a thickness of about 3 (nm) having a Hf/(Hf+Si) ratio greater than or equal to 50 percent is illustratively deposited by the MOCVD method. As necessary, the film property of the deposited hafnium silicate film is improved by heat treatment such as annealing including oxygen and nitridation treatment, and a HfSiON film 26 is formed. After that, a hafnium silicate film with a thickness of about 1 (nm) having a Hf/(Hf+Si) ratio of about 10 percent is deposited on the HfSiON film 26 using the same film formation method, and the film property is improved by the heat treatment and the like as required, then a HfSiON film 27 is formed.

Next, a polycrystalline silicon film 28 is deposited on the entire surface of the HfSiON film 27. The thickness of the polycrystalline silicon film 28 is, for example, 100 (nm). It is noted that amorphous silicon may be used instead of polycrystalline silicon.

Next, as shown in FIG. 11, a mask 32, the polycrystalline silicon film 28 and the HfSiON films 26, 27 are processed by using the mask 32 illustratively made of the silicon nitride film, and a gate pattern is formed.

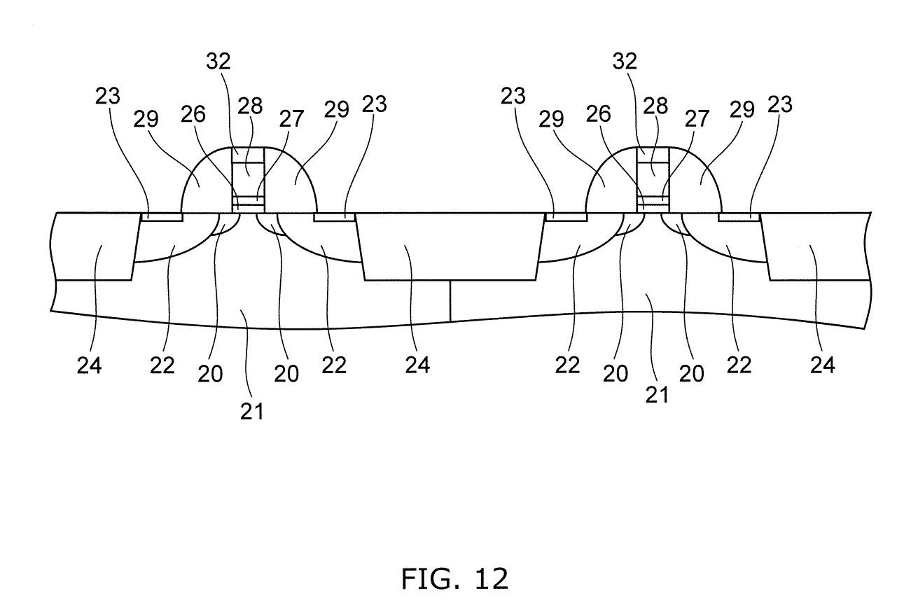

Next, after ion implantation is used for an extension region (LDD: Light Doped Drain region), a side wall insulating film 29 (FIG. 12) is formed on the side wall of the gate pattern, subsequently ion implantation is used for a source/drain region. At this time, a gate electrode of a p-type MIS structure is implanted with boron as an impurity.

Then, annealing is performed for recovery of damage caused by the ion implantation and activation of impurities. Thus a shallow impurity diffusion region (extension region) 20 and a deep impurity diffusion region (source/drain region) 22 are formed as shown in FIG. 12. Subsequently, as necessary, the surface of the source/drain region 22 is silicidized and a metal silicon compound region 23 is formed on its surface in order to decrease the resistance of the source/drain region 22.

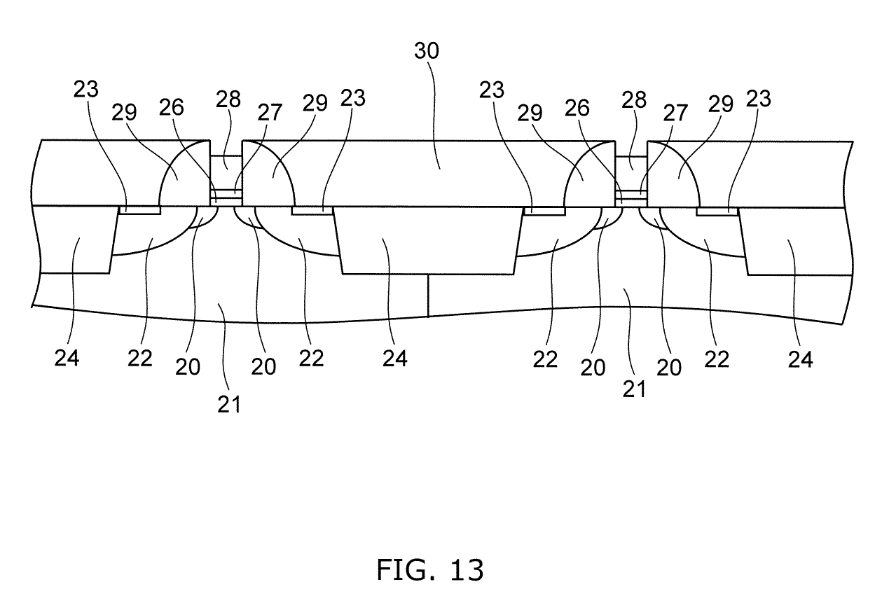

Next, a thin silicon nitride film liner is deposited on the entire surface and furthermore, an insulating film 30 (FIG. 13) such as an oxide film is deposited, after that its surface is planarized by the CMP method or the like. At this time, the upper surface of the silicon nitride film mask 32 on the gate pattern is exposed. Anisotropic etching is performed on the mask 32 and the polycrystalline silicon layer 28 is exposed, as shown in FIG. 13. After surface treatment (cleaning treatment) is used for the surface of the exposed polycrystalline silicon layer 28 as pretreatment, nickel as silicide material is deposited on the entire surface. Hereafter, a thermal process at, for example, about 500 to 650° C. is used for a reaction between polycrystalline silicon and nickel in the entire region reaching the gate insulating film interface, and furthermore unreacted excessive nickel is removed using a mixed solution of sulfuric acid and hydrogen peroxide to form a nickel full silicide gate electrode 38 (FIG. 9).

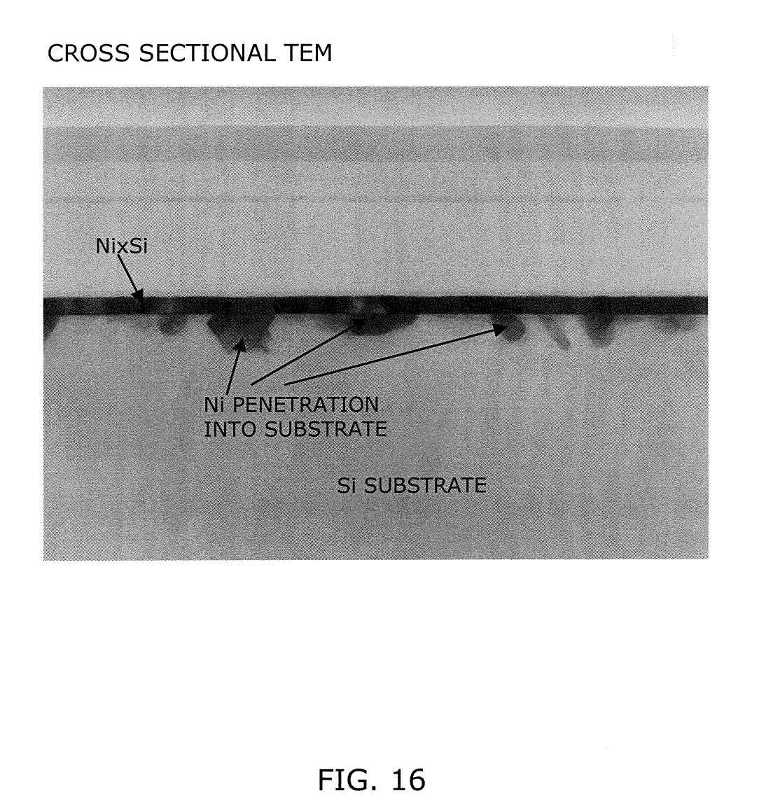

When polycrystalline silicon with diffused nickel is silicidized for adopting the hafnium silicate insulating film as the gate insulating film, boron illustratively contained in the gate electrode of the p-type MIS structure segregates to the gate insulating film interface and boron concentration in the vicinity of the interface increases. This causes a problem where nickel in the gate electrode penetrates the gate insulating film to diffuse into the silicon substrate as shown by a TEM image of FIG. 16, thereby the gate leak current increases.

However, in this embodiment, the HfSiON film 27 having the low Hf composition ratio (the Hf/(Hf+Si) ratio is less than or equal to 30 percent) is provided on the side of the gate insulating film in contact with the gate electrode. Therefore, it can be suppressed that nickel contained in the gate electrode penetrates the gate insulating film and diffuses into the silicon substrate, thus producing no trouble such as a gate leak. As a result, the gate structure of which films are thinned while assuring a low leak current can be formed with a high yield.

### Third Embodiment

In this embodiment, on formation of the hafnium silicate film, first the silicon substrate surface is exposed and the interface oxide film is formed, and subsequently the hafnium silicate film is deposited. At this time, controlling (decreasing gradually) the flow amount supplied of the hafnium source gas allows the hafnium silicate film to be formed, the film having the reduced composition ratio of Hf on the surface side serving as the interface between the gate electrode. The Hf composition ratio on the surface side of the hafnium silicate film is low, but its film thickness is thick. Therefore, the heat treatment for improving the film property allows the hafnium silicate film to have performance equivalent to the hafnium silicate insulating film with constant Hf concentration by illustratively controlling the heat treatment time and nitridation time.

Moreover, the Hf composition ratio in the hafnium silicate film is varied only by controlling the amount supplied of the hafnium source gas, therefore, film damage can be suppressed.

Also in this embodiment, the Hf composition ratio on the side of the gate insulating film in contact with the gate electrode is low. Therefore, it can be suppressed that nickel contained in the gate electrode penetrates the gate insulating film and diffuses into the silicon substrate, thus producing no trouble such as the gate leak.

### Fourth Embodiment

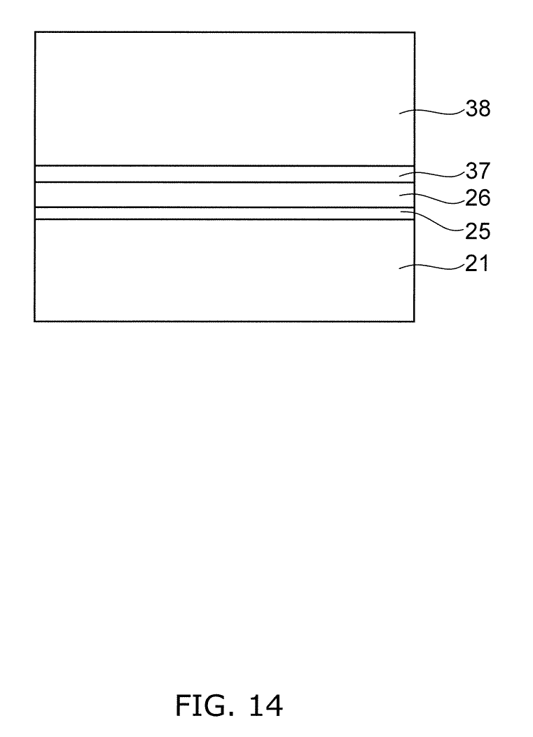

FIG. 14 is a schematic cross section enlarging the MIS structure portion of a semiconductor device according to a fourth embodiment of the invention.

In this embodiment, a metal silicate insulating film (including nitride) and a silicon nitride film as a so-called high-k film having a higher dielectric constant than the silicon oxide film are used for the gate insulating film.

The silicon oxide film 25 illustratively formed by the thermal oxidation method is formed on the surface of the channel formation region as shown in FIG. 14. The HfSiON film 26 is formed on the silicon oxide film 25. The Hf/(Hf+Si) ratio of the HfSiON film 26 is, for example, greater than or equal to 50 percent. A silicon nitride film 37 is formed on the HfSiON film 26. After the formation of the HfSiON film 26, the silicon nitride film 37 with a thickness of about, for example, 0.5 (nm) is deposited.

The gate electrode 38 is formed on the silicon nitride film 37. The gate electrode 38 is the nickel silicide gate electrode obtained by causing the silicidization reaction of nickel diffused from the upper portion after deposition and processing of polycrystalline silicon.

According to this embodiment, the silicon nitride film containing no Hf is provided on the side of the gate insulating film in contact with the gate electrode. Therefore, it can be suppressed that nickel contained in the gate electrode penetrates the gate insulating film and diffuses into the silicon substrate, thus producing no trouble such as the gate leak. Moreover, the silicon nitride film has an advantage in its capability to be formed at a low temperature so as to keep a channel profile of a transistor steep.

The inventors measured leak currents for each structure, the structure (the second, third embodiments) provided with the HfSiON film (Low-Hf layer) 27 having the low composition ratio of Hf on the side of the gate insulating film in contact with the gate electrode, the structure (the fourth embodiment) provided with the silicon nitride film 37 on the side of the gate insulating film in contact with the gate electrode, and the structure (comparative example) not provided with the HfSiON film 27 having the low composition ratio of Hf in the gate insulating film of the second embodiment.

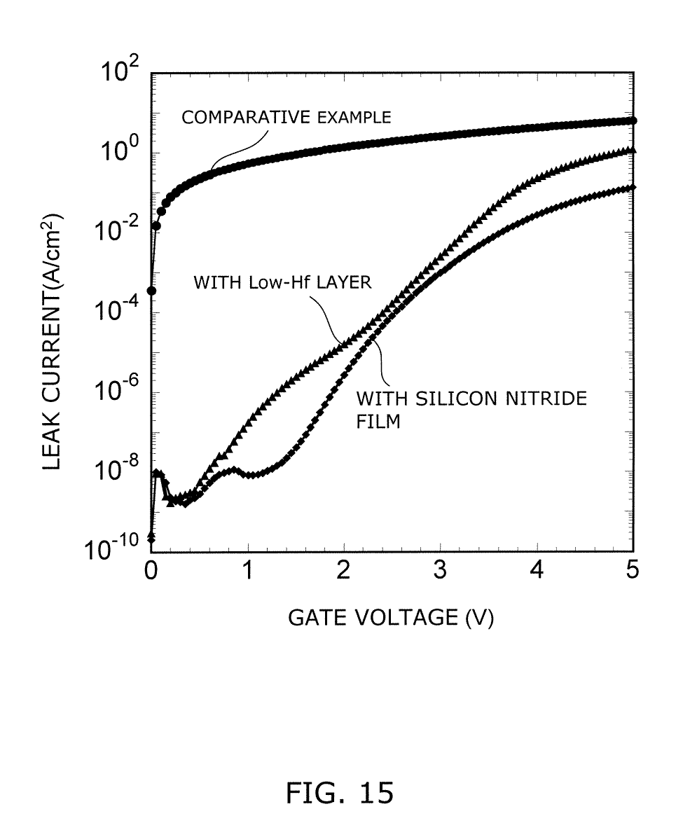

FIG. 15 is a graphic diagram showing its result, the horizontal axis representing the gate voltage (V), and the vertical axis representing the leak current (A/cm²).

This result indicates that providing the HfSiON film (Low-Hf layer) 27 having the low composition ratio of Hf and the silicon nitride film 37 on the side of the gate insulating film in contact with the gate electrode makes it possible to reduce the leak current significantly compared with not providing these films (comparative example).

In the second through third embodiments previously described, a method for silicidization of the gate electrode is not limited in particular. For example, the thermal process for silicidization may be performed in a plurality of separate steps as well as one step annealing. In this case, the necessary amount of nickel and silicon may be different from the amount in one step annealing. Moreover, the necessary amount of nickel varies with a relationship between the formed silicide composition and polycrystalline silicon, but has no dependence specifically. Furthermore, all portions of the gate electrode are not needed to be completely silicidized (full silicidization), and a structure with nickel in contact with a part of the substrate surface and boron existing therein may be approved. In that case, the structure may not always serve as the gate electrode of a transistor.

In the planarization process of the interlayer insulating film (oxide film) 30 shown in FIG. 13, the gate pattern may be exposed by etching such as RIE or the like, after etching by the CMP method is stopped in a state of leaving the oxide film 30 slightly instead of exposing polycrystalline silicon or the silicon nitride film mask in the upper portion of the gate pattern directly.

An SOI (Silicon On Insulator) substrate having a silicon activated layer formed on the insulating film as well as a normal silicon substrate can be used for the substrate. Surface orientation of the substrate is not limited, and a substrate where silicon is grown using the silicon substrate as a seed may be used.

Moreover, the invention can be applied to a transistor having a multilevel structure in the channel gate electrode portion such as a Fin-type as well as a planar transistor.

Furthermore, in the invention, Aluminum (Al), Yttrium (Y), Zirconium (Zr), Tantalum (Ta) or the like can be also used for a metal in the metal silicate insulating film other than Hafnium (Hf). It is supposed that even if those metal silicate insulating films is used, the same effect as that obtained for using the hafnium silicate insulating film described above is obtained.

1. A semiconductor device comprising:
a silicon oxide film;
a metal silicate insulating film provided on the silicon oxide film and having a higher dielectric constant than the silicon oxide film; and
a gate electrode provided on the metal silicate insulating film,
a composition ratio of a metal element in the metal silicate insulating film on a side closer to the gate electrode being lower than a composition ratio of the metal element in the metal silicate insulating film on a side closer to the silicon oxide film.

2. The semiconductor device according to claim 1, wherein the gate electrode is made of polycrystalline silicon.

3. The semiconductor device according to claim 2, wherein a composition ratio of metal/(metal+silicon) in the metal silicate insulating film on the side closer to the gate electrode is from 1 percent to 6 percent.

4. The semiconductor device according to claim 2, wherein a composition ratio of metal/(metal+silicon) in the metal silicate insulating film on the side closer to the silicon oxide film is equal to or greater than 50 percent.

5. The semiconductor device according to claim 2, wherein the metal silicate insulating film is a hafnium silicate insulating film.

6. The semiconductor device according to claim 5, wherein the hafnium silicate insulating film is a HfSiON film.

7. The semiconductor device according to claim 6, wherein a nitrogen content in the HfSiON film on the side closer to the gate electrode is higher than the nitrogen content in the HfSiON film on the side closer to the silicon oxide film.

8. The semiconductor device according to claim 1, wherein the gate electrode is a nickel silicide gate electrode, at least a part of the nickel silicide gate electrode containing boron.

9. The semiconductor device according to claim 8, wherein a composition ratio of metal/(metal+silicon) in the metal silicate insulating film on the side closer to the nickel silicide gate electrode is from 0 percent to 30 percent.

10. The semiconductor device according to claim 8, wherein a composition ratio of metal/(metal+silicon) in the metal silicate insulating film on the side closer to the silicon oxide film is equal to or greater than 50 percent.

11. The semiconductor device according to claim 8, wherein the metal silicate insulating film is a hafnium silicate insulating film.

12. The semiconductor device according to claim 11, wherein the hafnium silicate insulating film is a HfSiON film.

13. A semiconductor device comprising:
a metal silicate insulating film;
a silicon nitride film provided on the metal silicate insulating film; and
a nickel silicide gate electrode provided on the silicon nitride film, at least a part of the nickel silicide gate electrode containing boron.

14. The semiconductor device according to claim 13, wherein the metal silicate insulating film is provided on a silicon oxide film.

15. The semiconductor device according to claim 14, wherein a composition ratio of metal/(metal+silicon) in the metal silicate insulating film on a side closer to the silicon oxide film is equal to or greater than 50 percent.

16. The semiconductor device according to claim 13, wherein the metal silicate insulating film is a hafnium silicate insulating film.

17. The semiconductor device according to claim 16, wherein the hafnium silicate insulating film is a HfSiON film.

18. A method of manufacturing a semiconductor device, comprising:
depositing a metal silicate insulating film on a silicon oxide film by supplying a metal source gas, a silicon source gas and an oxygen source gas to a surface of the silicon oxide film, the metal silicate insulating film having a higher dielectric constant than the silicon oxide film, and
forming a gate electrode on the metal silicate insulating film,
the depositing including reducing the supplying amount of the metal source gas during deposition of the metal silicate insulating film.

19. The method of manufacturing the semiconductor device according to claim 18, wherein the metal source gas includes hafnium.

20. The method of manufacturing the semiconductor device according to claim 19, wherein a HfSiO film is formed by the depositing, and
further comprising forming a HfSiON film by nitriding the HfSiO film.
